(19) United States
(12) Patent Application Publication
(10) Pub. No.: US 2013/0162304 A1
(43) Pub. Date: Jun. 27, 2013

(54) Gate Line Driver Capable Of Controlling Slew Rate Thereof

(71) Applicant: In-suk KIM, Suwon-si (KR)

(72) Inventor: In-suk KIM, Suwon-si (KR)

(73) Assignee: SAMSUNG ELECTRONICS CO., LTD., Suwon-si (KR)

(21) Appl. No.: 13/605,249

(22) Filed: Sep. 6, 2012

(30) Foreign Application Priority Data
Dec. 21, 2011 (KR) 10-2011-0139215

(51) Int. Cl. H03K 3/00

(52) U.S. Cl. 327/109

(57) ABSTRACT

A gate line driver including an output buffer configured to receive a driving signal and output a driving voltage, and a slew rate controller including at least one capacitor and a switch connected in series to the at least one capacitor, the switch configured to selectively, electrically connect the at least one capacitor between an input terminal and an output terminal of the output buffer according to a slew rate control signal to control a slew rate of the output buffer.

### CROSS-REFERENCE TO RELATED APPLICATIONS

This application claims the benefit of Korean Patent Application No. 10-2011-0139215, filed on Dec. 21, 2011, in the Korean Intellectual Property Office, the disclosure of which is incorporated herein in its entirety by reference.

### BACKGROUND

One or more aspects of the inventive concepts relate to a liquid crystal display (LCD) device, and more particularly, to a gate line driver of an LCD device, in which a slew rate of the gate line driver is controlled to reduce an output peak current, thereby minimizing noise, caused by electromagnetic interference (EMI).

A gate line driver sequentially drives gate lines of an LCD device. A plurality of pixel transistors and a plurality of pixel capacitors are connected to each of the gate lines of the LCD device. A gate line driving voltage is generated and output by using an output buffer with good driving capability to drive the gate lines with a voltage that changes from a gate ‘off’ voltage to a gate ‘on’ voltage or from the gate ‘on’ voltage to the gate ‘off’ voltage within a predetermined time period. The voltage of the output buffer has a maximum rate of change per unit time otherwise known as a slew rate. If the slew rate is excessively high, the amount of a peak current increases, thus generating noise, caused by EMI.

### SUMMARY

The inventive concepts provides a driving buffer capable of controlling a slew rate of a driving voltage to prevent electromagnetic interference (EMI) from occurring, and a gate line driver of a liquid crystal display (LCD) device.

According to an aspect of the inventive concept, there is provided a gate line driver including an output buffer configured to receive a driving signal and output a driving voltage; and a slew rate controller including at least one capacitor and a switch configured to switch according to a slew rate control signal. The switch connected in series to the at least one capacitor such that the at least one capacitor is electrically connected to an input terminal and an output terminal of the output buffer to control a slew rate of the output buffer, if the switch is closed.

The slew rate controller may include a plurality of switches configured to switch according to the slew rate control signal, each switch of the plurality of switches are connected in series to an associated capacitor of a plurality of capacitors such that capacitors connected to the turned on switches may be connected in parallel between the input and output terminals of the output buffer, if assocaited switches from among the plurality of switches are closed.

The plurality of capacitors may have different capacitances.

The slew rate control signal may be set outside the gate line driver.

The output buffer may be an inverter.

According to another aspect of the inventive concepts, there is provided a gate line driver configured to drive a gate line of a display panel, the gate line driver including a buffer unit including a plurality of output buffers that are each configured to activate by receiving a corresponding buffer signal, the activated output buffers are configured to output a driving voltage; and a slew rate controller configured to generate and outpute the buffer signals according to control signals.

At least one output buffer from among the plurality of output buffers may be configured to be activated to generate the driving voltage by setting logic levels of the control signals.

The slew rate controller may include a plurality of logic circuits each configured to generate a first buffer signal and a second buffer signal according to a driving signal and a corresponding control signal. Each of the plurality of output buffers may be deactivated or activated to generate the driving voltage, according to the first and second buffer signals received from a corresponding logic circuit.

Each of the plurality of output buffers may include a PMOS transistor and an NMOS transistor that are connected in series. The PMOS transistor may be turned on or off according to the first buffer signal, and the NMOS transistor may be turned on or off according to the second buffer signal.

In the plurality of output buffers, ratios between widths and lengths of the PMOS transistors or ratios between widths and lengths of the NMOS transistors may be different from one another.

When the control signal has a first logic level, the first buffer signal and the second buffer signal may alternately turn on the PMOS transistor or the NMOS transistor, according to the driving signal.

When the control signal has a second logic level, the first buffer signal may turn off the PMOS transistors, and the second buffer signal may turn off the NMOS transistor, regardless of the gate driving signal.

The buffer unit may further include a basic buffer configured to receive the driving signal and generate the driving voltage.

The buffer unit may further include a first buffer unit configured to apply the driving voltage from a first end of the gate line, and a second buffer unit configured to apply the driving voltage from a second end of the gate line. The slew rate controller may include a first slew rate controller configured to control output buffers of the first buffer unit according to a first type control signal; and a second slew rate controller configured to control output buffers of the second buffer unit according to a second type control signal.

The gate line driver may control the output buffers of the first buffer unit and the output buffers of the second buffer unit to be activated or deactivated by setting logic levels of the first type control signal and the second type control signal.

According to another aspect of the inventive concepts, there is provided a gate line including one or more output buffers and a slew rate controller. The one or more output buffers each configured to output a driving voltage in response to a received input voltage and the slew rate controller is configured to selectively reduce a slew rate of the driving voltage according to a slew rate control signal.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of a gate line driver according to an example embodiment of the inventive concepts;

FIG. 2 is a detailed circuit diagram of the gate line driver of FIG. 1;

FIGS. 3A to 3C are circuit diagrams of a circuit equivalent to the gate line driver and a driving load of FIG. 2, and a timing diagram of the gate line driver, according to an example embodiment of the inventive concepts;

FIGS. 4A to 4C are circuit diagrams of a circuit equivalent to the gate line driver and the driving load of FIG. 2, and a timing diagram of the gate line driver, according to another example embodiment of the inventive concepts;

FIG. 5 is a circuit diagram of a gate line driver according to another example embodiment of the inventive concepts;

FIG. 6 is a block diagram of a gate line driver according to another example embodiment of the inventive concepts;

FIG. 7 is a detailed circuit diagram of the gate line driver of FIG. 6;

FIG. 8 is a circuit diagram of a logic circuit illustrated in FIG. 7, according to an example embodiment of the inventive concepts;

FIG. 9 is a circuit diagram of a gate line driver according to another example embodiment of the inventive concepts;

FIG. 10 is a circuit diagram of a gate line driver according to another example embodiment of the inventive concepts; and

FIG. 11 is a block diagram of a display system according to an example embodiment of the inventive concepts.

### DETAILED DESCRIPTION OF THE EMBODIMENTS

Hereinafter, example embodiments of the inventive concepts will be described in detail with reference to the accompanying drawings. The inventive concepts may, however, be embodied in many different forms and should not be construed as being limited to the embodiments set forth herein. Rather, these embodiments are provided so that this disclosure will be thorough and complete and will fully convey the inventive concepts to those of ordinary skill in the art. It would be obvious to those of ordinary skill in the art that the above exemplary embodiments are to cover all modifications, equivalents, and alternatives falling within the scope of the inventive concept. Like reference numerals denote like elements throughout the drawings. In the drawings, the size and thickness of layers and regions may be exaggerated for clarity.

The terminology used herein is for the purpose of describing particular embodiments only and is not intended to be limiting of the inventive concept. As used herein, the singular forms, ‘a’, ‘an’, and ‘the’ are intended to include the plural forms as well, unless the context clearly indicates otherwise. It will be further understood that the terms, ‘comprise’, ‘include’, or ‘has’ when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, expressions such as “at least one of,” when preceding a list of elements, modify the entire list of elements and do not modify the individual elements of the list.

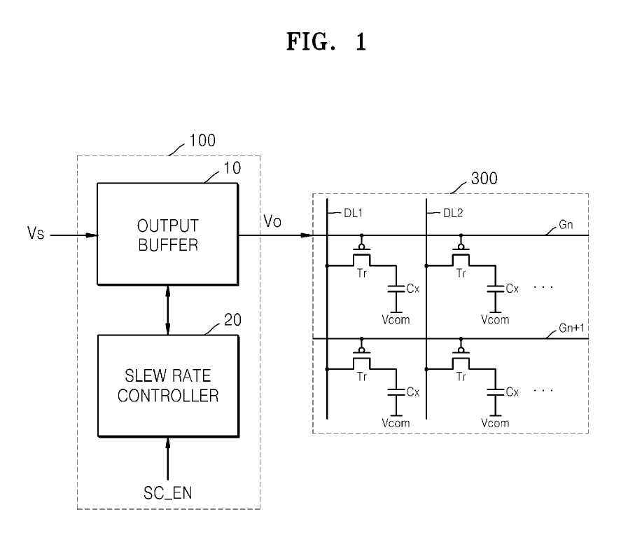

FIG. 1 is a block diagram of a gate line driver 100 according to an example embodiment of the inventive concepts. For convenience of explanation, a display panel 300 is also illustrated.

Referring to FIG. 1, the gate line driver 100 drives a gate line Gn of the display panel 300. The gate line Gn is connected to gate terminals of pixel transistors Tr of pixels forming a vertical line in the display panel 300. The gate line driver 100 applies a driving voltage Vo to the gate terminals of the pixel transistors Tr to turn on or off the pixel transistors Tr.

The gate line driver 100 includes an output buffer 10 and a slew rate controller 20. The output buffer 10 receives a driving signal Vs and then generates and outputs driving voltage Vo. The slew rate controller 20 controls a slew rate of the output buffer 10 according to a slew rate control signal SC_EN.

Specifically, the output buffer 10 receives the driving signal Vs via an input terminal thereof, and generates the driving voltage Vo. Then, the output buffer 10 applies the driving voltage Vo to the gate line Gn. In other words, the output buffer 10 drives the gate line Gn. The driving voltage Vo may be a signal, the phase of which is the same as or different from the phase of the driving signal Vs.

The slew rate controller 20 controls the slew rate of the output buffer 10 according to the slew rate control signal SC_EN to vary the driving voltage Vo corresponding to the driving signal Vs at a desired speed. The slew rate means an instantaneous rate of change in a voltage or current, and is defined as a maximum variation in the voltage or current per unit time. The slew rate may represent the performance of an amplifier or a buffer. Thus, the slew rate controller 20 controls the rate of change in the driving voltage Vo output from the output buffer 10.

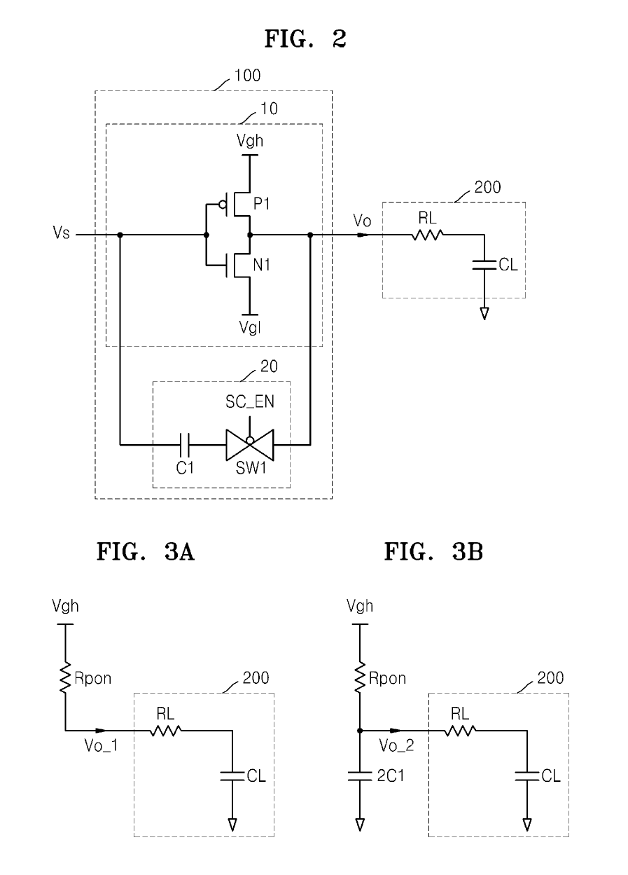

FIG. 2 is a detailed circuit diagram of the gate line driver 100 of FIG. 1. For convenience of explanation, a driving load 200 connected to an output terminal of the output buffer 10 is also illustrated. In the driving load 200, a load resistor RL and a load capacitor CL may be a resistor and a capacitor that are obtained by modeling a parasite resistor of a gate line GLn of the display panel 300 and a gate terminal of a pixel transistor Tr of each pixel of the display panel 300 of FIG. 1, respectively. The load resistor RL may have a resistance of about several hundreds to several thousands ohm and the load capacitor CL may have a capacitance of about several tens to several hundreds pF, but may be vary according to the size and type of the display panel 300.

Referring to FIG. 2, the output buffer 10 may include a PMOS transistor P1 and an NMOS transistor N1. Although for convenience of explanation, FIG. 2 illustrates that the output buffer 10 includes a pair of the transistors P1 and N1, any pair of additional transistors may further be included in the output buffer 10. Also, the output buffer 10 may include other switching devices that operate similar to the PMOS transistor P1 and the NMOS transistor N1.

Referring to FIG. 2, in the PMOS transistor P1, a gate high voltage Vgh is applied to a source terminal, a driving signal Vs input to the output buffer 10 is supplied to a gate terminal, and a drain terminal is connected to a drain terminal of the NMOS transistor N1 and an output terminal of the output buffer 10. In the NMOS transistor N1, a gate low voltage Vgl is applied to a source terminal, a driving signal Vs is supplied to a gate terminal, and the drain terminal is connected to the drain terminal of the PMOS transistor P1 and the output terminal of the output buffer 10.

The driving signal Vs may be a voltage, e.g., the gate low voltage Vgl, that turns on the PMOS transistor P1 and turns off the NMOS transistor N1, or may be a voltage, e.g., the gate high voltage Vgh, that turns on the NMOS transistor N1 and turns off the PMOS transistor P1.

The PMOS transistor P1 and the NMOS transistor N1 may be controlled by the driving signal Vs to operate as switches. The PMOS transistor P1 outputs the gate high voltage Vgh as the driving voltage Vo via the drain terminal thereof when the PMOS transistor P1 is turned on, and the NMOS transistor N1 outputs the gate low voltage Vgl as the driving voltage Vo via the drain terminal thereof when the NMOS transistor N1 is turned on. For example, if the driving signal Vs is the gate high voltage Vgh, then the NMOS transistor N1 is turned on to output the gate low voltage Vgl as the driving voltage Vo. If the driving signal Vs is the gate low voltage Vgl, then the PMOS transistor P1 is turned on to output the gate high voltage Vgh as the driving voltage Vo. An input signal input to and an output signal output from the output buffer 10 have opposite voltages, and the output buffer 10 thus operates as an inverter.

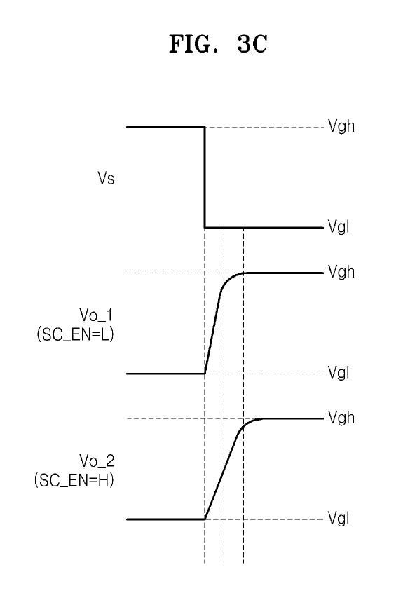

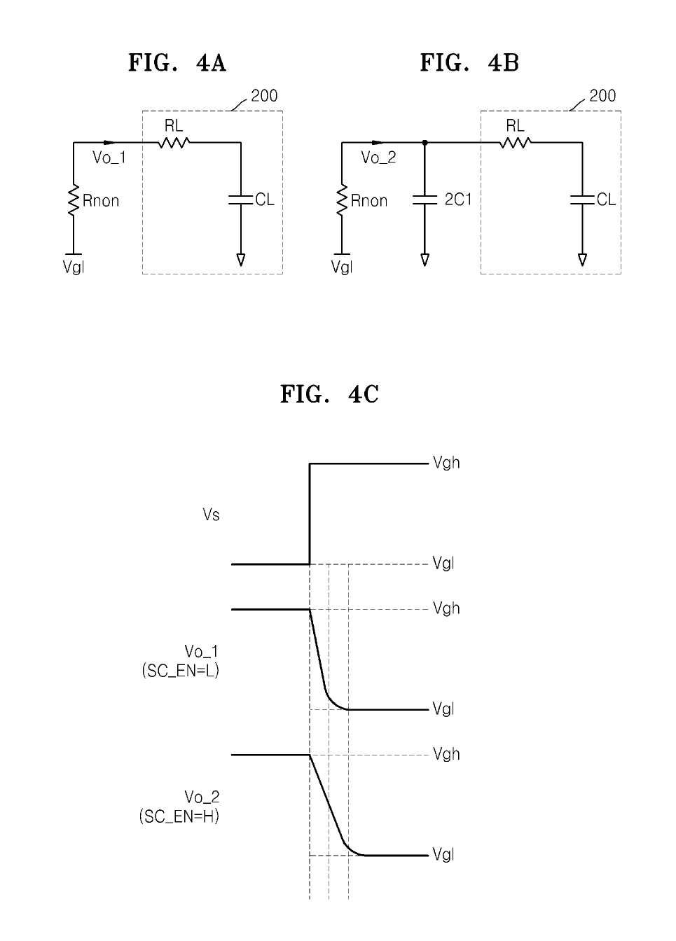

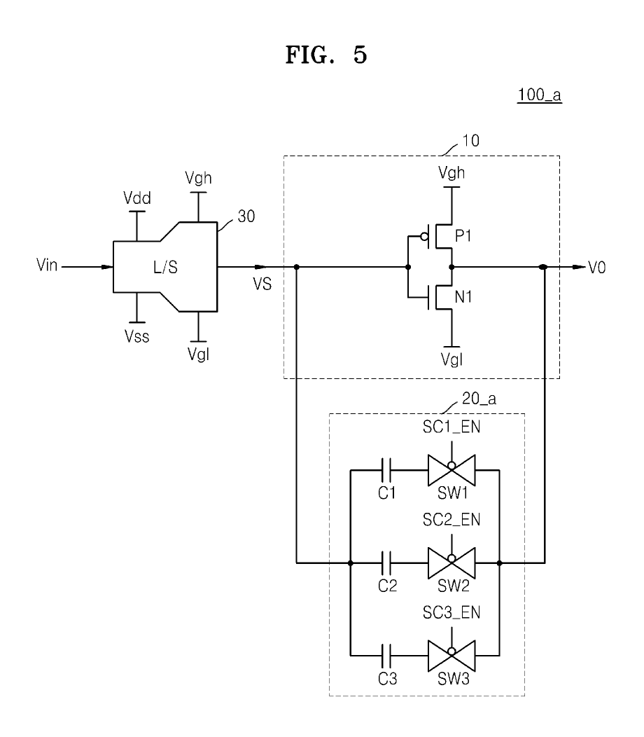

The slew rate controller 20 includes a capacitor C1 and a switch SW1. A first end of the capacitor C1 is connected to an input terminal of the output buffer 10, and a second end of the capacitor C1 is connected to a first end of the switch SW1. The first end of the switch SW1 is connected to the second end of the capacitor C1 and a second end of the switch SW1 is connected to the output terminal of the output buffer 10. The switch SW1 is turned on or off according to a slew rate control signal SC_EN. For example, the switch SW1 is turned on when the slew rate control signal SC_EN has a high level and is turned off when the slew rate control signal SC_EN has a low level. When the switch SW1 is turned on, the capacitor C1 is electrically connected to the input and output terminals of the output buffer 10. When the capacitor C1 is electrically connected to the input and output terminals of the output buffer 10, the slew rate of the output buffer 10 is lowered, as will be described in detail with reference to FIGS. 3A to 4C below.

FIGS. 3A and 3B are circuit diagrams of a circuit equivalent to the gate line driver 100 and the driving load 200 of FIG. 2 when the PMOS transistor P1 of FIG. 2 is turned on, according to embodiments of the inventive concept.

FIG. 3A illustrates a case where the slew rate control signal SC_EN of FIG. 2 has the low level and the capacitor C1 of FIG. 2 is not connected to the output buffer 10. Referring to FIG. 3A, the PMOS transistor P1 may be modeled as an on-resistor Rpon. Although for convenience of explanation, FIG. 3A illustrates that the PMOS transistor P1 includes only the on-resistor Rpon, the PMOS transistor P1 may further include other parasitic devices. A resistance of the on-resistor Rpon may be determined by, for example, a ratio between the width and length of the PMOS transistor P1, and a threshold voltage Vth.

FIG. 3B illustrates a case where the slew rate control signal SC_EN has the high level and the capacitor C1 is connected to the output buffer 10. As in FIG. 3A, the PMOS transistor P1 that is turned on is modeled as an on-resistor Rpon. The capacitor C1 illustrated as being connected between the input and output terminals of the output buffer 10 in FIG. 2, is modeled as a load capacitor 2C1 that has a capacitance that is double the capacitance of capacitor C1 and is connected to the output terminal of the output buffer 10, according to the miller effect. Thus, the equivalent circuit of FIG. 3B further includes a load capacitor, compared to when the capacitor C1 is not connected to the output buffer 10 as illustrated in FIG. 3A.

FIG. 3C is a timing diagram of the gate line driver 100 of FIG. 2, according to an example embodiment of the inventive concepts. In particular, FIG. 3C is a timing diagram of the gate line driver 100 when a driving signal Vs goes from a gate high voltage Vgh to a gate low voltage Vgl. In FIG. 3C, ‘Vo_1’ denotes a waveform of a driving voltage Vo in the equivalent circuit of FIG. 3A, i.e., when the slew rate control signal SC_EN is the low level, and ‘Vo_2’ denotes a waveform of the driving voltage Vo in the equivalent circuit of FIG. 3B, i.e., when the slew rate control signal SC_EN has the high level.

When the driving signal Vs changes from the gate high voltage Vgh to the gate low voltage Vgl, both the driving voltages Vo_1 and Vo_2 go from the gate low voltage Vgl to the gate high voltage Vgh. However, due to the on-resistor Rpon of the PMOS transistor P1, a resistance-capacitance (RC) delay is caused by the on-resistor Rpon, the load resistor RL, and the load capacitor CL. Thus, as illustrated in FIG. 3C, a change in the driving voltages Vo_1 and Vo_2 are delayed compared to in the driving signal Vs. However, the greater a resistance, the greater a capacitance, the greater the RC delay. Thus, the change in a logic level of the driving voltage Vo_2 in the equivalent circuit of FIG. 3B occurs later than in the driving voltage Vo_1 in the equivalent circuit of FIG. 3A, as illustrated in FIG. 3C.

FIGS. 4A and 4B are circuit diagrams of a circuit equivalent to the gate line driver 100 and the driving load 200 of FIG. 2 when the NMOS transistor N1 of FIG. 2 is turned on, according to embodiments of the inventive concept.

FIG. 4A illustrates a case where the slew rate control signal SC_EN of FIG. 2 has the low level and the capacitor C1 is not connected to the output buffer 10. Referring to FIG. 4A, the NMOS transistor N1 may be modeled as an on-resistor Rnon.

FIG. 4B illustrates a case where the slew rate control signal SC_EN has the high level and the capacitor C1 is connected to the output buffer 10. As in FIG. 3B, the capacitor C1 illustrated as being connected between the input and output terminals of the output buffer 10 in FIG. 2, may be modeled as a load capacitor 2C1 that has a capacitance that is double the capacitance of capacitor C1 and is connected to the output terminal of the output buffer 10, according to the miller effect. Thus, the equivalent circuit of FIG. 4B further includes a load capacitor, compared to when the capacitor C1 is not connected to the output buffer 10 as illustrated in FIG. 4A.

FIG. 4C is a timing diagram of the gate line driver 100 of FIG. 2, according to another example embodiment of the inventive concepts. In particular, FIG. 4C is a timing diagram of the gate line driver 100 when a driving signal Vs changes from a gate low voltage Vgl to a gate high voltage Vgh. In FIG. 4C, ‘Vo_1’ denotes a waveform of a driving voltage Vo in the equivalent circuit of FIG. 4A, i.e., when the slew rate control signal SC_EN has the low level, and ‘Vo_2’ denotes a waveform of the driving voltage Vo in the equivalent circuit of FIG. 4B, i.e., when the slew rate control signal SC_EN has the high level.

When the driving signal Vs goes from the gate low voltage Vgl to the gate high voltage Vgh, both the driving voltages Vo_1 and Vo_2 go from the gate high voltage Vgh to the gate low voltage Vgl. However, due to the on-resistor Rpon of the NMOS transistor N1, an RC delay is caused by the on-resistor Rpon, the load resistor RL, and the load capacitor CL. Since the equivalent circuit of FIG. 4B further includes the load capacitor 2C1 compared to the equivalent circuit of FIG. 4A, the degree of an RC delay occurring in the equivalent circuit of FIG. 4B is greater than in the equivalent circuit of FIG. 4A. Thus, the change in a logic level of the driving voltage Vo_2 in the equivalent circuit of FIG. 4B occurs later than in the driving voltage Vo_1 in the equivalent circuit of FIG. 4A, as illustrated in FIG. 4C.

As described above with reference to FIGS. 3A to 4C, the slew rate of the output buffer 10 is lowered when the capacitor C1 is connected between the input and output terminals of the output buffer 10 as illustrated in FIG. 2.

Referring back to FIG. 2, when the switch SW1 is turned on to connect the capacitor C1 between the input and output terminals of the output buffer 10, the capacitor C1 may feed the driving voltage Vo back to the output unit 10 to reduce the slew rate of the driving signal Vs supplied to the gate terminals of the transistors P1 and N1 of the output buffer 10. Since the slew rate of the driving signal Vs input to the output buffer 10 is lowered, the slew rate of the driving voltage Vo output from the output buffer 10 is also lowered.

As described above, the slew rate of the output buffer 10 may be lowered by connecting the capacitor c1 between the input and output terminals of the output buffer 10. Thus, if the slew rate of the output buffer 10 is high, the slew rate control signal SC_EN may close switch SW1 to connect the capacitor c1 between the input and output terminals of the output buffer 10, thereby reducing the slew rate of the output buffer 10.

FIG. 5 is a circuit diagram of a gate line driver 100_{—}a according to another example embodiment of the inventive concepts. Referring to FIG. 5, the gate line driver 100_{—}a includes an output buffer 10 and a slew rate controller 20_{—}a. The gate line driver 100_{—}a may further include the level shifter 30.

The output buffer 10 receives a driving signal Vs, and generates and outputs a driving voltage Vo. The slew rate controller 20_{—}a controls the slew rate of the output buffer 10 according to slew rate control signals SC1_EN to SC3_EN.

The output buffer 10 includes a PMOS transistor P1 and an NMOS transistor N1, and receives the driving signal Vs from the level shifter 30, and generates the driving voltage Vo from the driving signal Vs. The driving voltage Vo is output as a gate low voltage Vgl when the driving signal Vs is the gate high voltage Vgh, and is output as a gate high voltage Vgh when the driving signal Vs is the gate low voltage Vgl. The output buffer 10 is as described above with reference to FIG. 2 and is thus not described again here.

The slew rate controller 20_{—}a includes a plurality of capacitors C1, C2, and C3, and a plurality of switches SW1, SW2, and SW3 that are respectively connected to ends of capacitors C1, C2, and C3. The slew rate controller 20_{—}a changes the slew rate of the output buffer 10 according to the slew rate control signals SC1_EN to SC3_EN.

Although FIG. 5 illustrates that the slew rate controller 20_{—}a includes the three capacitors C1 to C3 and the three switches SW1 to SW3, the inventive concepts is not limited thereto and the total number and capacitances of capacitors and the total number of switches may vary according to a desired range of slew rate.

In the slew rate controller 20_{—}a, the plurality of switches SW1 to SW3 are turned on or off according to the slew rate control signals SC1_EN to SC3_EN, respectively. If at least two switches are turned on from among the plurality of switches SW1 to SW3, then capacitors connected to the turned on switches are connected in parallel. Thus, it is possible to obtain the same result as when a capacitor, the capacitance of which is equal to the sum of the capacitances of the capacitors connected in parallel is connected to input and output terminals of the output buffer 10.

When the plurality of capacitors C1 to C3 have different capacitances, the slew rate control signals SC1_EN to SC3_EN that respectively control the plurality of switches SW1 to SW3 may have the following logic levels:

TABLE 1
Slew rate control signal status

| | SC1_EN | SC2_EN | SC3_EN |
|---|---|---|---|
| Case 1 | L | L | L |
| Case 2 | H | L | L |
| Case 3 | L | H | L |
| Case 4 | H | H | L |
| Case 5 | L | L | H |
| Case 6 | H | L | H |
| Case 7 | L | H | H |
| Case 8 | H | H | H |

In Case 1, all of the capacitors C1 to C3 of the slew rate controller 20_{—}a are not connected to the output buffer 10, whereas in Case 8, all the capacitors C1 to C3 are connected to the output buffer 10. In between Case 1 and Case8 lie examples where one or more of the capacitors are enabled. For example, if the first capacitor C1 has a capacitance of 10 pF, the second capacitor C2 has a capacitance of 20 pF, and the third capacitor C3 has a capacitance of 50 pF, then capacitors having a capacitance of 30 pF are connected between the input and output terminals of the output buffer 10 (Case 3) and capacitors having a capacitance of 60 pF are connected between the input and output terminals of the output buffer 10 (Case 6).

If the capacitors C1 to C3 each have the same capacitance, the slew rate control signals SC1_EN to SC3_EN that control the plurality of switches SW1 to SW3 may have the following logic levels:

TABLE 2
Slew rate control signal status

| | SC1_EN | SC2_EN | SC3_EN |
|---|---|---|---|
| Case 1 | L | L | L |
| Case 2 | H | L | L |
| Case 3 | H | H | L |
| Case 4 | H | H | H |

Since the capacitors C1 to C3 each have the same capacitance, the more capacitors connected between the input and output terminals of the output buffer 10, the greater a total capacitance, resulting in a lower slew rate of the driving voltage Vo. For example, if the capacitors C1 to C3 each have a capacitance of 20 pF, then capacitors having a capacitance of 0 pF, 20 pF, 40 pF, or 60 pF are connected between the input and output terminals of the output buffer 10 according to the logic levels of the slew rate control signals SC1_EN to SC3_EN during Case 1, Case 2, Case 3 and Case 4, respectively.

Referring to Tables 1 and 2, the higher the order of Cases, the higher a total capacitance of capacitors connected between the input and output terminals of the output buffer 10, resulting in a lower slew rate of the output buffer 10. Thus, the slew rate of the output buffer 10 may be adjusted to a desired level by changing the logic levels of the slew rate control signals SC1_EN to SC3_EN.

The gate line driver 100_{—}a may further include the level shifter 30. The level shifter 30 converts a voltage (logic level) of a signal and then outputs the converted signal. If a logic voltage is applied to the gate line driver 100_{—}a and the difference between the logic voltage and a driving voltage (a power supply voltage of the output buffer 10) is large, then the output buffer 10 cannot be stably controlled by using the logic voltage. Thus, the logic voltage is converted into the driving voltage by using the level shifter 30 to stably control the output buffer 10. For example, the gate control signal Vin having a logic voltage, e.g., a first power supply voltage Vdd or a second power supply voltage Vss, may be received, converted into the driving signal Vs having a driving voltage Vgh or Vgl, and then the driving signal Vs may be output. The driving signal Vs has the gate high voltage Vgh when the gate control signal Vin has the first power supply voltage Vdd, and has the gate low voltage Vgl when the control signal Vin has the second power supply voltage Vss.

The level shifter 30 may include an inverter (not shown). If the level shifter 30 includes an inverter, the driving signal Vs has the gate low voltage Vgl when the gate control signal Vin has the first power supply voltage Vdd, and has the gate high voltage Vgh when the gate control signal Vin has the second power supply voltage Vss. The level shifter 30 would be obvious to those of ordinary skill in the art and will not further be described in detail here.

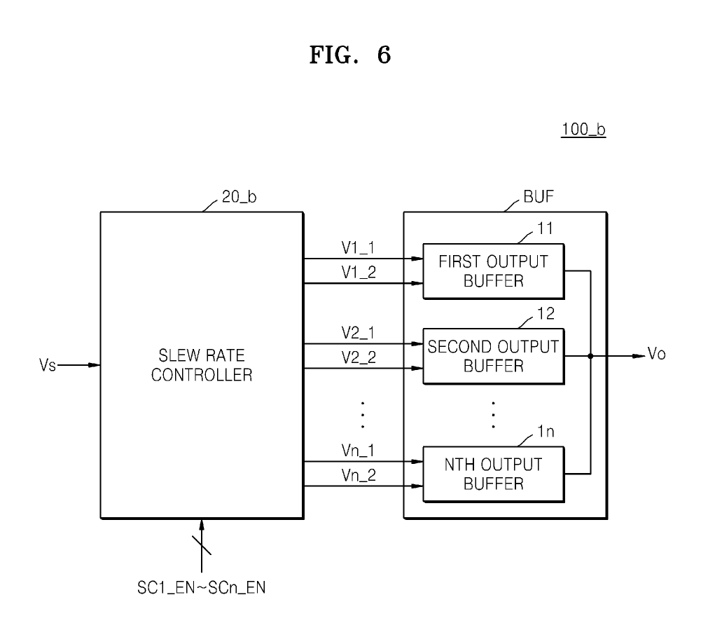

FIG. 6 is a block diagram of a gate line driver 100_{—}b according to another embodiment of the inventive concept. Referring to FIG. 6, the gate line driver 100_{—}b includes a buffer unit BUF and a slew rate controller 20_{—}b.

The slew rate controller 20_{—}b receives a driving signal Vs, and outputs buffer signals V1_1 to Vn_2 according to control signals SC1_EN to SCn_EN. The buffer unit BUF includes a plurality of output buffers 11 to ln. An activated output buffer from among the plurality of output buffers 11 to 1n generates and outputs a driving voltage Vo according to the buffer signals Vn_1 and Vn_2.

More specifically, the slew rate controller 20_{—}b receives the driving signal Vs and the control signals SC1_EN to SCn_EN. The control signals SC1_EN to SCn_EN are used to control a slew rate of the gate line driver 100_{—}b, and may be set by a user outside the gate line driver 100_{—}b. However, the inventive concepts is not limited thereto and the control signals SC1_EN to SCn_EN may be set in various manners. For example, the control signals SC1_EN to SCn_EN may be automatically set according to conditions of driving the gate line driver 20_{—}b. The slew rate controller 20_{—}b generates and outputs n pairs of buffer signals V1_1 and V1_2 through to Vn_1 and Vn_2 for respectively controlling the output buffers 11 to 1n included in the buffer unit BUF, according to the control signals SC1_EN to SCn_EN. Here, n denotes an integer that is greater than 'er. The n pairs of buffer signals are supplied to the output buffers 11 to 1n in the buffer unit BUF to control activation of the output buffers 11 to ln.

The buffer unit BUF includes the n output buffers 11 to 1n. Each of the n output buffers 11 to 1n is activated to generate the driving voltage Vo or is deactivated, according to a pair of buffer signals received from the slew rate controller 20_{—}b.

The slew rate of the driving voltage Vo is high when an output buffer having good driving capability is activated or when a number of activated output buffers is large. However, when the slew rate of the driving voltage Vo is high, the amount of a peak current increases and electromagnetic interference (EMI) may thus occur. Thus, logic levels of the control signals SC1_EN to SCn_EN may be changed to control the driving voltage Vo to have a desired slew rate while preventing EMI from occurring due to an increase in the amount of the peak current.

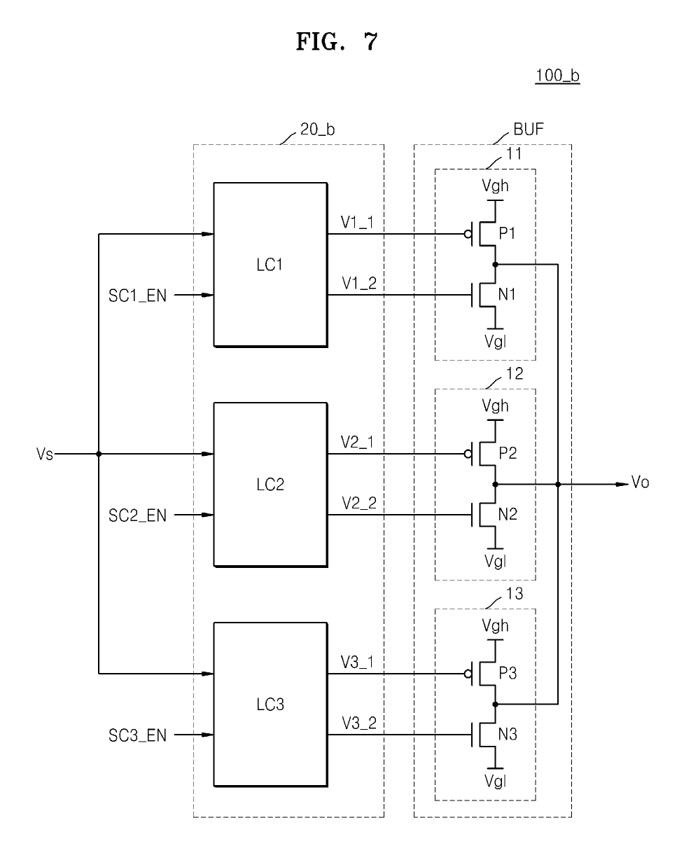

FIG. 7 is a detailed circuit diagram of the gate line driver 100_{—}b of FIG. 6. The gate line driver 100_b includes the slew rate controller 20_{—}b and the buffer unit BUF. Although for convenience of explanation, FIG. 7 illustrates that the buffer unit BUF includes three output buffers 11, 12, and 13 and the slew rate controller 20_{—}b includes three logic circuits LC1, LC2, and LC3, the inventive concepts is not limited thereto and the total numbers of output buffers and logic circuits are not limited.

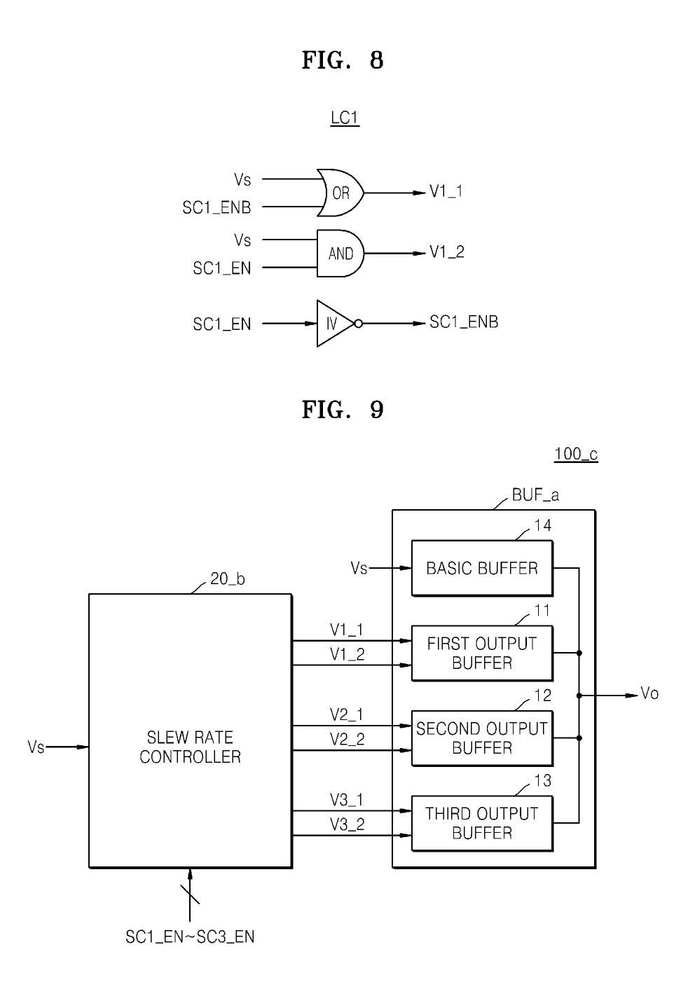

The slew rate controller 20_{—}b includes the three logic circuits LC1, LC2, and LC3. The logic circuits LC1, LC2, and LC3 receive control signals SC1_EN to SC3_EN and generate pairs of buffer signals V1_1 and V1_2, buffer signals V2_1 and V2_2, and buffer signals V3_1 and V3_2, respectively. Operations of the logic circuits LC1, LC2, and LC3 will be described with reference to FIG. 8 below.

FIG. 8 is a circuit diagram of the logic circuit LC1 illustrated in FIG. 7, according to an example embodiment of the inventive concepts. For example, operations of the first logic circuit LC1 are described from among the logic circuits LC1, LC2, and LC3 here.

The first logic circuit LC1 includes an OR gate OR, an AND gate AND, and an inverter IV. The first logic circuit LC1 receives a gate driving signal Vs and a first control signal SC1_EN, and generates a first buffer signal V1_1 and a second buffer signal V1_2.

The first buffer signal V1_1 may be generated using the OR gate OR. The OR gate OR receives a first negative control signal SC1_ENB and the driving signal Vs, and generates the first buffer signal V1_1. The first negative control signal SC1_ENB may be obtained by inverting the first control signal SC1_EN by using the inverter IV. If the first control signal SC1_EN has a first logic level, i.e., high level, then the first negative control signal SC1_ENB is low level. Since the first negative control signal SC1_ENB that is low level is supplied to one end of the OR gate OR, an output of the OR gate OR is determined by the driving signal Vs supplied to the other end of the OR gate OR. If the first control signal SC1_EN has a second logic level, e.g., low level, then the first negative control signal SC1_ENB is high level. Thus, the OR gate OR is maintained to be high level regardless of the driving signal Vs.

The second buffer signal V1_2 may be generated using the AND gate AND. The driving signal Vs and the first control signal SC1_EN are respectively supplied to one end and the other end of the AND gate AND. If the first control signal SC1_EN has the first logic level, e.g., high level, then an output of the AND gate AND is determined by the driving signal Vs supplied to the other end of the AND gate AND. If the first control signal SC1_EN has the second logic level, e.g., low level, then the AND gate AND is maintained to be low level regardless of the driving signal Vs.

The structure and operations of the first logic circuit LC1 have been described above with reference to FIG. 8, but the inventive concepts is not limited thereto. A type of a logic circuit that receives the first control signal SC1_EN and the gate driving signal Vs and generates first buffer signal V1_1 and the second buffer signal V1_2 is not limited. Also, the first negative control signal SC1_ENB has been described as being obtained by inverting the first control signal SC1_ENB, but the first logic circuit LC1 may not include the inverter IV and may receive the first negative control signal SC1_ENB from the outside.

Referring back to FIG. 7, structures of the second logic circuit LC2 and the third logic circuit LC3 are the same as that of the first logic circuit LC3 described above with reference to FIG. 8, and are not be described again here.

A gate high voltage Vgh and a gate low voltage Vgl may be power supply voltages of the logic circuits LC1, LC2, and LC3 and the output buffers 11, 12, and 13. Thus, the gate high voltage Vgh is output when the first buffer signals V1_1, V2_1, and V3_1 and the second buffer signals V1_2, V2_2, and V3_2 are high level, and the gate low voltage Vgl is output when the first buffer signals V1_1, V2_1, and V3_1 and the second buffer signals V1_2, V2_2, and V3_2 are low level.

Next, the buffer unit BUF will be described in greater detail. The buffer unit BUF includes the output buffers 11, 12, and 13. Each of the output buffers 11, 12, and 13 is operated by supplying a pair of buffer signals thereto.

The first output buffer 11 includes a PMOS transistor P1 and an NMOS transistor N1. The first output buffer 11 receives a pair of buffer signals V1_1, V1_2 from the first logic circuit LC1, and generates a driving voltage Vo.

The first buffer signal V1_1 is supplied to a gate terminal of the PMOS transistor P1 to turn on or off the PMOS transistor P1. The second buffer signal V1_2 is supplied to a gate terminal of the NMOS transistor N1 to turn on or off the NMOS transistor N1. That is, the PMOS transistor P1 and the NMOS transistor N1 are controlled using different signals.

As described above with reference to FIG. 8, when the first control signal SC1_EN is high level, voltages of the first buffer signal V1_1 and the second buffer signal V1_2 are the same as a voltage of the gate control signal Vs. Thus, in the first output buffer 11, the same voltage is applied to the gate terminals of the PMOS transistor P1 and NMOS transistor N1. For example, when the gate high voltage Vgh is applied to the gate terminals of the PMOS transistor P1 and NMOS transistor N1, the NMOS transistor N1 is turned on to output the gate low voltage Vg1 as the driving voltage Vo. When the gate low voltage Vgl is applied to the gate terminals of the PMOS transistor P1 and NMOS transistor N1, the PMOS transistor P1 is turned on to output the gate high voltage Vgh as the driving voltage Vo.

However, when the first control signal SC1_EN is low level, the first output buffer 11 is deactivated. The gate high voltage Vgh is output as the first buffer signal V1_1, the first buffer signal V1_1 is supplied to the gate terminal of the PMOS transistor P1 included in the first output buffer 11, and the PMOS transistor P1 is thus turned off. Also, when the gate low voltage Vgl is output as the second buffer signal V1_2 and the second buffer signal V1_2 is supplied to the gate terminal of the NMOS transistor N1 included in the first output buffer 11, then the NMOS transistor N1 is turned off. Since both the transistors P1 and N1 of the first output buffer 11 are turned off, an output terminal of the first output buffer 11 has a high impedance (High-Z) state.

Structures and operations of the second output buffer 12 and the third output buffer 13 are the same as those of the first output buffer 11, and are not thus described again here.

An operation of the gate line driver 100_{—}b when the first control signal SC1_EN and second control signal SC2_EN are, for example, high level, and the third control signal SC3_EN is, for example, low level, will now be described. Since the first control signal SC1_EN and the second control signal SC2_EN are high level, the first logic circuit LC1 and the second logic circuit LC2 outputs the first buffer signals V1_1 and V2_1 and the second buffer signals V1_2 and V2_2, the voltages of which are equal to a voltage of the driving signal Vs. Thus, the first output buffer 11 and the second output buffer 12 output the gate high voltage Vgh or the gate low voltage Vgl as the driving voltage Vo, according to the driving signal Vs.

Since the third control signal SC3_EN is low level, the third logic circuit LC3 outputs the gate high voltage Vgh as the first buffer signal V3_1 and the gate low voltage Vgl as the second buffer signal V3_2, regardless of the driving signal Vs. Thus, both the PMOS transistor P3 and the NMOS transistor N3 of the third output buffer 13 are turned off, and an output of the third output buffer 13 is thus maintained to a high impedance (High-Z) state.

Thus, since the first output buffer 11 and the second output buffer 12 are activated, the third output buffer 13 is deactivated, gate lines of the display panel are driven by the first output buffer 11 and second output buffer 12.

In this case, the driving capabilities of the first to third output buffers 11 to 13 may be controlled to be different from one another by differently adjusting a ratio between the widths and lengths of the transistors included in the first to third output buffers 11 to 13. For example, if the ratio between the widths and lengths of the PMOS transistors P1, P2, and P3 in the first to third output buffers 11 to 13 is 1:2:4, then the ratio between the driving capabilities of the first to third output buffers 11 to 13 is 1:2:4 when the driving voltage Vo goes from the gate high voltage Vgh to the gate low voltage Vgl.

Also, if the ratio between the widths and lengths of the NMOS transistor N1, N2, and N3 included in the first to third output buffers 11, 12, and 13 is 1:2:4, then the ratio between the driving capabilities of the first to third output buffers 11, 12, and 13 is 1:2:4 when the driving voltage Vo goes from the gate low voltage Vgl to the gate high voltage Vgh.

Furthermore, the driving capability of each of the first to third output buffers 11, 12, and 13 may be controlled to be different when the driving voltage Vo goes from the gate high voltage Vgh to the gate low voltage Vgl and when the driving voltage Vo goes from the gate low voltage Vgl to the gate high voltage Vgh by changing differently controlling the ratio between the widths and lengths of one of the PMOS transistors P1, P2, and P3 and one of the NMOS transistors N1, N2, and N3. For example, if the ratio between the widths and lengths of the PMOS transistor P1 and the NMOS transistor N1 of the first output buffer 11 is 2:1, then the ratio between the driving capabilities of the first output buffer 11 when the driving voltage Vo goes from the gate low voltage Vgl to the gate high voltage Vgh and when the driving voltage Vo goes from the gate high voltage Vgh to the gate low voltage Vgl is 2:1.

The number of cases of logic levels of the first to third control signals SC1_EN, SC2_EN, and SC3_EN for activating or deactivating the first to third output buffers 11, 12, and 13 will be described below.

In the gate line driver 100_{—}b of FIG. 7, logic levels of the first to third control signals SC1_EN, SC2_EN, and SC3_EN may be set as follows:

TABLE 3
Slew rate control signal status

| | SC1_EN | SC2_EN | SC3_EN |
|---|---|---|---|
| Case 1 | H | L | L |
| Case 2 | L | H | L |
| Case 3 | H | H | L |
| Case 4 | L | L | H |
| Case 5 | H | L | H |
| Case 6 | L | H | H |
| Case 7 | H | H | H |

Since the number of the first to third control signals SC1_EN, SC2_EN, and SC3_EN is three, the number of cases of logic levels of the first to third control signals SC1_EN, SC2_EN, and SC3_EN may thus be eight. However, since at least one control signal from among the first to third control signals SC1_EN, SC2_EN, and SC3_EN should be maintained to be high level, the number of cases of the logic levels of the first to third control signals SC1_EN, SC2_EN, and SC3_EN may be seven as shown in Table 3. If all the first to third control signals SC1_EN, SC2_EN, and SC3_EN are low level, all the first to third output buffers 11, 12, and 13 are deactivated and thus cannot generate the driving voltage Vo.

As described above, if the ratio between the driving capabilities of the first to third output buffers 11, 12, and 13 is 1:2:4, then the driving capability of the gate line driver 100_{—}b may be gradually improved by sequentially changing the logic levels of the first to third control signals SC1_EN, SC2_EN, and SC3_EN according to Cases 1 to 8. Thus, it is possible to generate the driving voltage Vo having a desired slew rate by controlling the first to third control signals SC1_EN, SC2_EN, and SC3_EN, but the inventive concepts is not limited thereto. It will be obvious to those of ordinary skill in the art that the logic levels of the first to third control signals SC1_EN, SC2_EN, and SC3_EN may vary according to the ratio between the driving capabilities of the first to third output buffers 11, 12, and 13.

As described above, in the gate line driver 100_{—}b of FIG. 7, the driving capabilities of the first to third output buffers 11, 12, and 13 may be controlled to be different from one another by changing the ratio between the widths and lengths of transistors therein. Also, the driving capability of the gate line driver 100_{—}b may be controlled by controlling a combination of output buffers to be activated from among the first to third output buffers 11, 12, and 13. Since the slew rate of the driving voltage Vo varies according to the driving capability of the buffer unit BUF, the driving voltage Vo output from the gate line driver 100_{—}b may have various slew rates.

FIG. 9 is a circuit diagram of a gate line driver 110_{—}c according to another example embodiment of the inventive concepts. The gate line driver 100_{—}c includes a slew rate controller 20_{—}b, and a buffer unit BUF_a. The buffer unit BUF_a includes a basic buffer 14, and output buffers 11, 12, and 13 that are controlled to be activated or deactivated according to control signals SC1_EN, SC2_EN, and SC3_EN. Although FIG. 9 illustrates that the buffer unit BUF_a includes the three output buffers 11, 12, and 13, the inventive concepts is not limited thereto.

Compared to the buffer unit BUF of FIG. 6, the buffer unit BUF_a of FIG. 9 further includes the basic buffer 14 that receives a gate driving signal Vs and generates a driving voltage Vo. In other words, the buffer unit BUF_a further includes the basic buffer 14 that may be maintained to be activated regardless of the control signals SC1_EN, SC2_EN, and SC3_EN, and generate and output the driving voltage Vo. The basic buffer 14 may be an inverter. Since the basic buffer 14 always generates the driving voltage Vo, all the first to third output buffers 11 to 13 may be deactivated by setting all the control signals SC1_EN, SC2_EN, and SC3_EN to be low level. Structures and operations of the slew rate controller 20_{—}b and the output buffers 11, 12, and 13 are the same as those of the slew rate controller 20_{—}b and the output buffers 11, 12, and 13 of FIG. 6 and are not described again here.

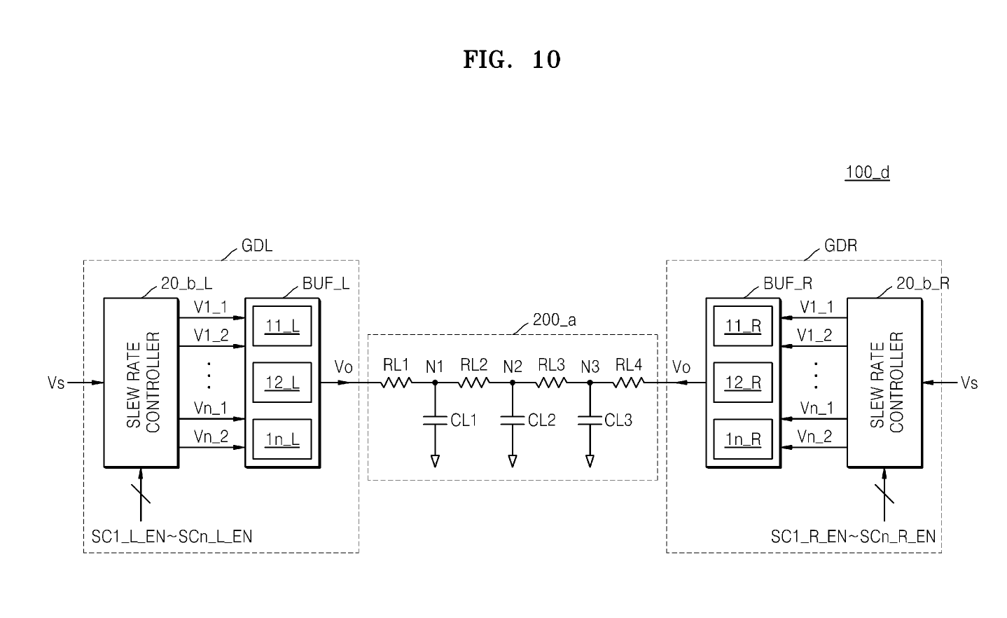

FIG. 10 is a circuit diagram of a gate line driver 100_{—}d according to another example embodiment of the inventive concepts. For convenience of explanation, a driving load 200_{—}a obtained by modeling a gate line of a display panel is also illustrated.

The gate line driver 100_{—}d includes a first driver GDL connected to a left side of the gate line of the display panel, and a second driver GDR connected to a right side of the gate line of the display panel. The first driver GDL and the second driver GDR may be each embodied as the gate line driver 100_{—}b of FIG. 6 or the gate line driver 100_{—}c of FIG. 9. Here, it is assumed that the first driver GDL and the second driver GDR have the same structure as that of the gate line driver 100_{—}b of FIG. 6.

The first driver GDL includes a first slew rate controller 20_{—}b_L and a first buffer unit BUF_L. The second driver GDR includes a second slew rate controller 20_{—}b_R and a second buffer unit BUF_R. The buffer unit BUF_L of the first driver GDL includes first to n^{th} output buffers 11_L to 1n_L. The buffer unit BUF_R of the second driver GDR includes first to n^{th} output buffers 11_R to 1n_R. The first to n^{th} output buffers 11_L to 1n_L in the first driver GDL are controlled to be activated or deactivated according to first type control signals SC1_L_EN to SCn_L_EN. The first to n^{th} output buffers 11_R to 1n_R in the second driver GDR are controlled to be activated or deactivated according to second type control signals SC1_R_EN to SCn_R_EN. Structures and operations of the slew rate controller 20_{—}b_L and the first to n^{th} output buffers 11_L to 1n_L included in the first driver GDL and the slew rate controller 20_{—}b_R and the first to n^{th} output buffers 11_R to 1n_R included in the second driver GDR of the second driver GDR are the same as those of the slew rate controller 20_{—}b and the first to n^{th} output buffers 11 to 1n of FIG. 6, and are not described again here.

Logic levels of the control signals SC1_L_EN to SCn_L_EN of FIG. 10 may be set as shown in Table 4 or 5 when n is ‘3’.

TABLE 4
Slew rate control signal status

| | SC1_L_EN | SC2_L_EN | SC3_L_EN | SC1_R_EN | SC2_R_EN | SC3_R_EN |
|---|---|---|---|---|---|---|
| Case 1 | H | L | L | H | L | L |
| Case 2 | L | H | L | L | H | L |
| Case 3 | H | H | L | H | H | L |
| Case 4 | L | L | H | L | L | H |
| Case 5 | H | L | H | H | L | H |
| Case 6 | L | H | H | L | H | H |
| Case 7 | H | H | H | H | H | H |

Referring to Table 4, the logic levels of the first type control signals SC1_L_EN to SC3_L_EN input to the first driver GDL are the same as those of the second type control signals SC1_R_EN to SC3_R_EN input to the second driver GDR. If the logic levels of these control signals are set as shown in Table 4, then at least one buffer from among the first to n^{th} output buffers 11_L to 1n_L of the output first driver GDL is activated to generate a driving voltage Vo, and at least one buffer from among the first to n^{th} output buffers 11_R to 1n_R of the second driver GDR is activated to generate the driving voltage Vo. Thus, since the driving voltage Vo is applied to both ends of the driving load 200_{—}a, a distribution of slew rates of the driving voltage Vo applied to terminals N1, N2, and N3 of the driving load 200_{—}a is narrower than when the driving voltage Vo is applied to only one end of the driving load 200_{—}a. In other words, since the same voltage is applied to both ends of the gate line of the display panel, the distribution of slew rates of the voltage applied to gate terminals of transistors included in pixels of the display panel may be reduced, thus improving image quality.

TABLE 5
Slew rate control signal status

| | SC1_L_EN | SC2_L_EN | SC3_L_EN | SC1_R_EN | SC2_R_EN | SC3_R_EN |
|---|---|---|---|---|---|---|
| Case 1 | H | L | L | L | L | L |
| Case 2 | L | H | L | L | L | L |
| Case 3 | H | H | L | L | L | L |
| Case 4 | L | L | H | L | L | L |
| Case 5 | H | L | H | L | L | L |
| Case 6 | L | H | H | L | L | L |
| Case 7 | H | H | H | L | L | L |

Referring to Table 5, the logic levels of the control signals SC1_L_EN, SC2_L_EN, SC3_L_EN, SC1_R_EN, SC2_R_EN, and SC3_R_EN may be set to deactivate all the first to n^{th} output buffers 11_R to 1n_R of the second driver GDR and to control activation of the first to n^{th} output buffers 11_L to 1n_L of the first driver GDL. However, the inventive concepts is not limited thereto, and it will be obvious to those of ordinary skill in the art that the logic levels of the control signals SC1_L_EN, SC2_L_EN, SC3_L_EN, SC1_R_EN, SC2_R_EN, and SC3_R_EN may be set to deactivate all the first to n^{th} output buffers 11_L to 1n_L of the first driver GDL and to control activation of the first to n^{th} output buffers 11_R to 1n_R of the second driver GDR.

As described above, it is possible to individually control the first buffer unit BUF_L of the first driver GDL and the second buffer unit BUF_R of the second driver GDR. Therefore, the slew rate of the gate line driver 100_{—}d may be controlled to have various levels.

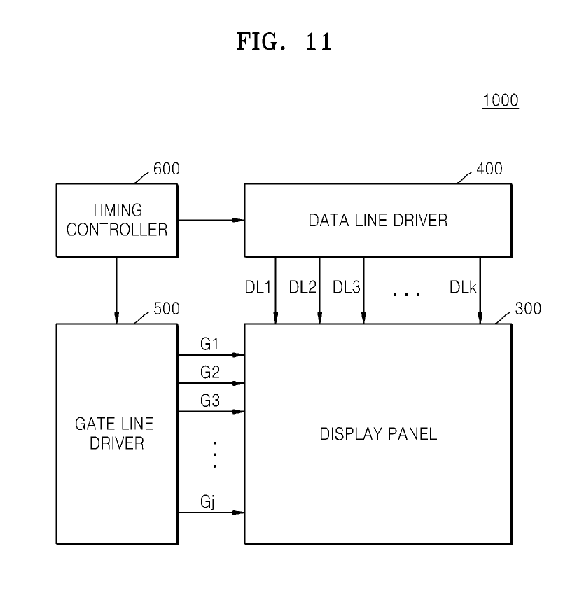

FIG. 11 is a block diagram of a display system 1000 according to an example embodiment of the inventive concepts. Referring to FIG. 11, the display system 1000 includes a display panel 300, a data line driver 400, a gate line driver 500, and a timing controller 600. The display panel 300 may be a liquid crystal display (LCD) device. The timing controller 600 generates a control signal for controlling the data line driver 400 and the gate line driver 500, and transmits a video signal received from the outside to the data line driver 400.

The data line driver 400 and the gate line driver 500 drive the display panel 300 according to the control signal received from the timing controller 600. The gate line driver 500 sequentially supplies scan signals G1, G2, G3, an Gj to rows of the display panel 300. Then, transistors connected to the rows are sequentially turned on as the scan signals G1, G2, G3, Gj are sequentially supplied to the rows. In this case, driving voltages DL1, DL2, . . . , DLk are applied to liquid crystal in the display panel 1000 from the data line driver 400 via the transistors in the rows. The gate line driver 400 may be the same as one of these gate line drivers according to the previous embodiments. Thus, it is possible to control a slew rate of an output buffer so as to reduce the amount of peak current, thereby preventing EMI from occurring. Furthermore, the image quality in the display panel 300, e.g., the LCD, may be improved by changing the slew rate of the display panel 300 according to load on each pixel transistor and each capacitor of the display panel 300.

The inventive concepts may be applied to any of flat panel display devices that are driven in a manner similar to a driving method of an LCD device, for example, an electro-chromic display (ECD), a digital mirror device (DMD), an actuated mirror device (AMD), a grating light value (GLV), a plasma display panel (PDP), an electro luminescent display (ELD), a light emitting diode (LED) display, and a vacuum fluorescent display (VFD). Also, an LCD device according to an example embodiment of the inventive concepts may be applied to a large-screen television (TV), a high-definition television (HDTV), a notebook computer, a camcorder, a display for use in a automobile, multimedia for information and telecommunication, the field of virtual reality, and the like.

While the inventive concepts has been particularly shown and described with reference to exemplary embodiments thereof, it will be understood that various changes in form and details may be made therein without departing from the spirit and scope of the following claims.

What is claimed is:

1. A gate line driver comprising:
an output buffer configured to receive a driving signal and output a driving voltage; and
a slew rate controller including at least one capacitor and a switch connected in series to the at least one capacitor, the switch configured to selectively, electrically connect the at least one capacitor between an input terminal and an output terminal of the output buffer according to a slew rate control signal to control a slew rate of the output buffer.

2. The gate line driver of claim 1, wherein the slew rate controller comprises:
a plurality of switches each configured to selectively, electrically connect in series an associated corresponding one of a plurality of capacitors according to the slew rate control signal such that the electrically connected capacitors are connected in parallel between the input and output terminals of the output buffer.

3. The gate line driver of claim 2, wherein the plurality of capacitors have different capacitances.

4. The gate line driver of claim 2, wherein the the slew rate control signal is set outside the gate line driver.

5. The gate line driver of claim 1, wherein the output buffer is an inverter.

6. A gate line driver configured to drive a gate line of a display panel, the gate line driver comprising:
a buffer unit including a plurality of output buffers that are each configured to activate by receiving a corresponding buffer signal, the activated output buffers are configured to output a driving voltage; and
a slew rate controller configured to generate and output the buffer signals according to control signals.

7. The gate line driver of claim 6, wherein at least one output buffer from among the plurality of output buffers is configured to activate to generate the driving voltage by setting logic levels of the control signals.

8. The gate line driver of claim 6, wherein the slew rate controller comprises a plurality of logic circuits each configured to generate a first buffer signal and a second buffer signal according to a driving signal and a corresponding control signal, and
each of the plurality of output buffers is configured to activate to generate the driving voltage, according to the first and second buffer signals received from a corresponding logic circuit.

9. The gate line driver of claim 8, wherein each of the plurality of output buffers comprises a PMOS transistor and an NMOS transistor that are connected in series,
wherein the PMOS transistor is turned on or off according to the first buffer signal, and
the NMOS transistor is turned on or off according to the second buffer signal.

10. The gate line driver of claim 9, wherein, in the plurality of output buffers, ratios between widths and lengths of the PMOS transistors or ratios between widths and lengths of the NMOS transistors are different from one another.

11. The gate line driver of claim 9, wherein, when the control signal has a first logic level, the first buffer signal and the second buffer signal alternately turn on the PMOS transistor or the NMOS transistor, according to the driving signal.

12. The gate line driver of claim 9, wherein, when the control signal has a second logic level, the first buffer signal turns off the PMOS transistors, and the second buffer signal turns off the NMOS transistor, regardless of the gate driving signal.

13. The gate line driver of claim 6, wherein the buffer unit further comprises a basic buffer configured to receive the driving signal and generate the driving voltage.

14. The gate line driver of claim 6, wherein
the buffer unit further includes,
a first buffer unit configured to apply the driving voltage from a first end of the gate line, and
a second buffer unit configured to apply the driving voltage from a second end of the gate line, and
the slew rate controller includes,
a first slew rate controller configured to control output buffers of the first buffer unit according to a first type control signal; and
a second slew rate controller configured to control output buffers of the second buffer unit according to a second type control signal.

15. The gate line driver of claim 14, wherein the gate line driver is configured to control the output buffers of the first buffer unit and the output buffers of the second buffer unit to be activated or deactivated by setting logic levels of the first type control signal and the second type control signal.

16. A gate line driver comprising:
one or more output buffers configured to output a driving voltage in response to a received input voltage; and
a slew rate controller configured to selectively reduce a slew rate of the driving voltage according to a slew rate control signal.

17. The gate line driver of claim 16, wherein the slew rate controller comprises at least one switch connected in series to a respective capacitor, the at least one switch configured to selectively couple the respective capacitor in parallel with the one or more output buffers to reduce a slew rate of the one or more output buffers.

18. The gate line driver of claim 16, wherein the slew rate controller comprises a plurality of logic circuits each configured to provide a pair of buffer voltages as the input voltage to a corresponding one of the one or more output buffers, and
the one or more output buffers are configured output the driving voltage according to the pair of buffer voltages received from a corresponding logic circuit.

19. The gate line driver of claim 18, wherein each of the plurality of logic circuits are configured to receive a control signal, and the one or more output buffers each comprising a pair of complimentary transistors,
the pair of complimentary transistors are configured to alternatively turn on according to the pair of buffer voltages, if the control signal has a first logic level, and
a first transistor of the pair of complimentary transistors is configured to turn off and a second transistor of the pair of complimentary transistors is configured to turn on irrespective of the pair of buffer voltages, if the control signal has a second logic level.

20. The gate line driver of claim 18, wherein the one or more output buffers further comprises a basic buffer configured to generate the driving voltage irrespective of the pair of buffer voltages.
